(19) United States
(12) Patent Application Publication
(10) Pub. No.: US 2014/0084760 A1
(43) Pub. Date: Mar. 27, 2014

(54) DISPLAY DEVICE

(71) Applicant: Gang Yu, Guangdong (CN)

(72) Inventor: Gang Yu, Guangdong (CN)

(73) Assignee: SHENZHEN CHINA STAR OPTOELECTRONICS TECHNOLOGY CO., LTD., Guangdong (CN)

(21) Appl. No.: 13/702,271

(22) PCT Filed: Sep. 25, 2012
(86) PCT No.: PCT/CN2012/081931

§ 371 Date: Dec. 5, 2012

(30) Foreign Application Priority Data
Sep. 24, 2012 (CN) 201210357902.1

(51) Int. Cl. H05K 5/02; H05K 5/00

(52) U.S. Cl. CPC H05K 5/0217; H05K 5/0017
USPC 312/7.2

(57) ABSTRACT

The present invention provides a display device, which comprises a front frame, a back plate, a back frame and a fixing member. The back frame comprises a loading surface used for loading the back plate and a plurality of side edges disposed around the loading surface, and the side edges of the back frame is fixed and connected to the front frame. The back plate is disposed on the loading surface of the back frame. The back plate comprises a back plate body and a plurality of side walls protruded on each of side edges of the back plate body. The front frame and the side walls of the back plate are fixed and connected by the fixing member, so as to fix and connect the front frame and back plate.

### FIELD OF THE INVENTION

The present invention relates to a technology field of display manufacture, and more particularly to a display device.

### BACKGROUND OF THE INVENTION

With the continuous development of display panel, the function requirement for each of components of display panel is higher and higher.

Referring now to FIG. 1, an exploded structural schematic view of a liquid crystal display (LCD) TV in a traditional technology is illustrated in FIG. 1. The LCD TV comprises a first front frame 11 and a first back frame 12, wherein the first front frame 11 and the first back frame 12 are used for an assembly of entire machine; and the LCD TV further comprises a second front frame 13 and a second back frame 14, wherein the second front frame 13 and the second back frame 14 are used for an assembly of backlight module.

Obviously, because it needs two front frames (the first front frame 11 and the second front frame 13) to finish the assembly of entire LCD TV, the actions of the first front frame 11 and the second front frame 13 are repeated, with similar functions, so as to cause material waste and cost increase.

Hence, how to simplify the LCD TV structure and to avoid the problems that the material waste and the cost increase are caused due to repeated actions of the two front frames, is become one of the technology problems that need to be solved in the LCD TV technology field.

### SUMMARY OF THE INVENTION

One of the objects of the present invention is to provide a display device, so as to simply a structure of a liquid crystal display (LCD) TV, and it can avoid a technology problem that the material waste and the cost increase are caused due to repeated actions of the two front frames and the cost increase.

For achieving the above-mentioned beneficial effect and solving the above-mentioned technology problem, the present invention constructs a display device, which comprises a front frame, a back plate and a back frame, wherein the back frame comprises a loading surface used for loading the back plate and a plurality of side edges disposed around the loading surface; and the side edges of the back frame is fixed and connected to the front frame;

wherein the back plate is disposed on the loading surface of the back frame; the back plate comprises a back plate body and a plurality of side walls protruded on each of the side edges of the back plate body; the side walls of the back plate and the back plate body are integrated into one body; and the side wall of the back plate is formed with a positioning hole; and

wherein the backlight module further comprises a fixing member; the fixing member comprises a spring and a positioning pillar; one end of the spring is connected to an inner side surface of the front frame, and the other end of the spring is connected to the positioning pillar; in a spring force action of the spring, the positioning pillar extends from the inner side surface of the front frame for a predetermined distance and extends into the positioning hole of the side wall, so as to engage and connect with the back plate; and the front frame and the side wall of the back plate are fixed and connected, so as to fix and connect the front frame and the back plate.

In one of the preferred embodiment of the present invention, the fixing member further comprises a limiting part; the limiting part comprises a limiting ring and a connecting portion connected to the limiting ring; and the limiting part is fixed and connected to the front frame by the connecting portion; and

wherein the positioning pillar comprises a first base and a positioning rod, and the positioning rod passes through the limiting ring, so that the limiting ring can limit the first base between the limiting part and the front frame.

In one of the preferred embodiment of the present invention, the display device further comprises a second base, which is disposed between the spring and the inner side surface of the front frame, and the second base is fixed and connected on the front frame.

In one of the preferred embodiment of the present invention, the connecting portion of the limiting part is fixed and connected to the second base.

In one of the preferred embodiment of the present invention, the positioning hole has a first depth, and the first depth is less than the thickness of the side wall.

In one of the preferred embodiment of the present invention, the positioning hole has a first depth, and the first depth is equal to the thickness of the side wall.

In one of the preferred embodiment of the present invention, the second base is fixed and connected on the inner side surface of the front frame by sticking.

In one of the preferred embodiment of the present invention, the front frame is fixed and connected to the back frame by sticking or screw-connection.

Another one of the objects of the present invention is to provide a display device, so as to simply a structure of a liquid crystal display (LCD) TV, and it can avoid a technology problem that the material waste and the cost increase are caused due to repeated actions of the two front frames.

For achieving the above-mentioned beneficial effect and solving the above-mentioned technology problem, the present invention constructs a display device, which comprises a front frame, a back plate and a back frame, wherein the back frame comprises a loading surface used for loading the back plate and a plurality of side edges disposed around the loading surface; and the side edges of the back frame is fixed and connected to the front frame;

wherein the back plate is disposed on the loading surface of the back frame, and the back plate comprises a back plate body and a plurality of side walls protruded on each of the side edges of the back plate body; and

wherein the backlight module further comprises a fixing member, and the front frame and the side wall of the back plate are fixed and connected by the fixing member, so as to fix and connect the front frame and the back plate.

In one of the preferred embodiment of the present invention, the side wall of the back plate is formed with a positioning hole; the fixing member comprises a spring and a positioning pillar; and one end of the spring is connected to an inner side surface of the front frame, and the other end of the spring is connected to the positioning pillar; and

wherein in a spring force action of the spring, the positioning pillar extends from the inner side surface of the front frame for a predetermined distance, and extends into the positioning hole of the side wall, so as to engage and connect with the back plate.

In one of the preferred embodiment of the present invention, the fixing member further comprises a limiting part, and the limiting part comprises a limiting ring and a connecting portion connected to the limiting ring, and the limiting part is fixed and connected to the front frame by the connecting portion; and

wherein the positioning pillar comprises a first base and a positioning rod, and the positioning rod passes through the limiting ring, so that the limiting ring can limit the first base between the limiting part and the front frame.

In one of the preferred embodiment of the present invention, the display device further comprises a second base, which is disposed between the spring and the inner side surface of the front frame, and the second base is fixed and connected on the front frame.

In one of the preferred embodiment of the present invention, the connecting portion of the limiting part is fixed and connected to the second base.

In one of the preferred embodiment of the present invention, the positioning hole has a first depth, and the first depth is less than the thickness of the side wall.

In one of the preferred embodiment of the present invention, the positioning hole has a first depth, and the first depth is equal to the thickness of the side wall.

In one of the preferred embodiment of the present invention, the second base is fixed and connected on the inner side surface of the front frame by sticking.

In one of the preferred embodiment of the present invention, the side walls of the back plate and the back plate body are integrated into one body.

In one of the preferred embodiment of the present invention, the front frame is fixed and connected to the back frame by sticking or screw-connection.

In comparison with the traditional technologies, in the present invention, a fixing member is disposed between an inner side surface of the front frame and a side wall of a back plate, so the front frame and the back plate are connected by the fixing member, and the front frame directly connects to the side wall of the back plate. Obviously, the present invention not only can simply the connection process, but also simply a structure of a liquid crystal display (LCD) TV, so that it can avoid a problem of material waste since needing two front frames in a traditional technology, and thus substantially save the cost.

For above-mention contents of the present invention can be best understood by referring to the following detailed description of the preferred embodiments and the accompanying drawings.

### DESCRIPTION OF THE DRAWINGS

FIG. 1 is an exploded structural schematic view of a liquid crystal display (LCD) TV in a traditional technology;

FIG. 2 is a cross-section structural schematic view of a display device according to a preferred embodiment of the present invention; and

FIG. 3 is a structural schematic view of a fixing member according to the preferred embodiment of the present invention.

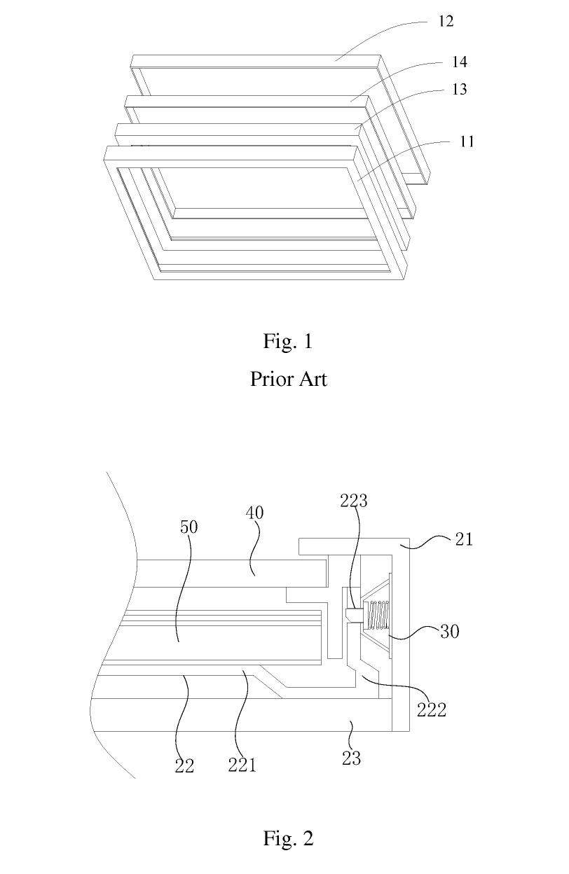

### DETAILED DESCRIPTION OF THE PREFERRED EMBODIMENTS

The foregoing objects, features and advantages adopted by the present invention can be best understood by referring to the following detailed description of the preferred embodiments and the accompanying drawings. Furthermore, the directional terms described in the present invention, such as upper, lower, front, rear, left, right, inner, outer, side and etc., are only directions referring to the accompanying drawings, so that the used directional terms are used to describe and understand the present invention, but the present invention is not limited thereto. In the drawings, the units with the similar structure use the same numerals.

Referring now to FIG. 2, a cross-section structural schematic view of a display device according to a preferred embodiment of the present invention is illustrated in FIG. 2.

The display device comprises a front frame 21, a back plate 22, a back frame 23 and a fixing member 30. The back frame 23 comprises a loading surface (not indicated) used for loading the back plate 22, and a plurality of side edges disposed around the loading surface, wherein the side edges of the back frame 23 is fixed and connected to the front frame 21. Preferably, the front frame 21 is fixed and connected to the back frame 23 by sticking or screw-connection. Certainly, they are also connected by the others connecting method, so they are not listed one by one here.

The back plate 22 is disposed on the loading surface 231 of the back frame 23. The back plate 22 comprises a back plate body 221 and a plurality of walls 222, wherein the side wall 222 is protruded and formed by each of the side edges of the back plate body 221. Preferably, the side walls 222 of the back plate 22 and the back plate body 221 are integrated into one body. Certainly, they are also connected by the others connecting method.

In the present invention, the front frame 21 and the side walls 222 of the back plate 22 are fixed and connected by the fixing member 30, so as to achieve the fixation and connection between the front frame 21 and the back plate 22.

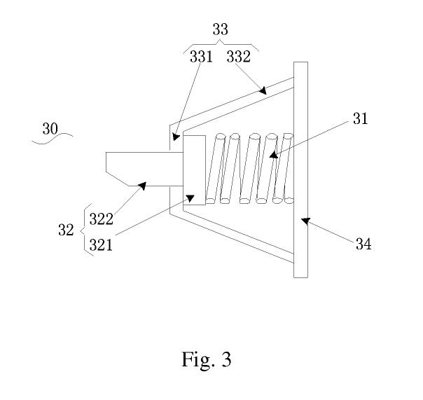

Referring now to FIG. 3, a structural schematic view of a fixing member according to the preferred embodiment of the present invention is illustrated in FIG. 3.

The fixing member 30 comprises a spring 31, a positioning pillar 32, a limiting part 33 and a second base 34. The positioning pillar 32 comprises a first base 321 and a positioning rod 322; and the limiting part 33 comprises a limiting ring 331 and a connecting portion 332.

In a specific embodiment process, the side wall 222 of the back plate 22 is formed with a positioning hole 223 (referring to FIG. 2). One end of the spring 31 is connected to an inner side surface (not indicated) of the front frame 21, and the other end of the spring 31 is connected to the positioning pillar 32. More specifically, in a spring force action of the spring 31, the positioning pillar 32 extends from the inner side surface of the front frame 21 for a predetermined distance, and extends into the positioning hole 223 of the side wall 222 of the back plate 22, so as to engage and connect with the back plate 22, and then the fixation and connection between the back plate 22 and the front frame 21 is finally achieved.

The positioning rod 322 of the positioning pillar 32 is connected to the first base 321. Preferably, the first base 321 and the positioning rod 322 are designed to integrate into one body. Certainly, they are also connected by the others connecting method. The positioning rod 322 passes through the limiting ring 331 of the limiting part 33, so that the limiting ring 331 can limit the first base 321 between the limiting part 33 and the front frame 21, so as to avoid the positioning rod 322 falls off from the fixing member 30.

The limiting ring 331 of the limiting part 33 is connected to the connecting portion 332, and the limiting part 33 is fixed and connected by the connecting portion 332.

The second base 34 of the fixing member 30 is disposed between the spring 31 and the inner side surface of the front frame 21. Preferably, the second base 34 is fixed and connected on the inner side surface of the front frame 21 by sticking or others, and the connecting portion 332 of the limiting part 33 is fixed and connected the second base 34.

In a specific embodiment process, the positioning hole 223 on the side wall 222 has a first depth, and the first depth is less than or equal to the thickness of the side wall 222.

An assembly process of the display device according to the present invention is as follows:

Firstly, disposing the back plate 22 on the loading surface of the back frame 23. Then, assembling an optical assembly (such as light guide plate 50) on the back plate 22, and disposing the panel 40 on the back plate 22.

After that, fixing and connecting the fixing member 30 on the inner side surface of the front frame 21, for example sticking the second base 34 on the inner side surface of the front frame 21. Then, fixing and connecting the side edges of the back frame 23 to the front frame 21 by a screw.

Because the side wall 222 of the back plate 22 is formed with a positioning hole 223 and the positioning rod 322 of the fixing member 30 is working in a spring force action of the spring, the positioning pillar 32 extends into the positioning hole 223 of the side wall 222, so as to fix the back plate 22. Hence, the fixation and connection between the back plate 22 and the front frame 21 is achieved, so as to finally finish the entire machine assembly.

Obviously, the present invention only needs one front frame 21 to achieve a connection between the front frame 21, the back plate 22 and the back frame 23. It not only can simply the connection process, but also simply a structure of a liquid crystal display (LCD) TV, so that it can avoid a problem of material waste since needing two front frames in a traditional technology, and thus substantially save the cost.

As described above, the present invention has been described with a preferred embodiment thereof and it is understood that many changes and modifications to the described embodiment can be carried out without departing from the scope and the spirit of the invention that is intended to be limited only by the appended claims.

1. A display device, comprising a front frame, a back plate and a back frame, wherein the back frame comprises a loading surface loading the back plate and a plurality of side edges disposed around the loading surface; and the side edges of the back frame is fixed and connected to the front frame;
wherein the back plate is disposed on the loading surface of the back frame; the back plate comprises a back plate body and a plurality of side walls protruded on each of side edges of the back plate body; the side walls of the back plate and the back plate body are integrated into one body; and the side wall of the back plate is formed with a positioning hole; and
wherein the backlight module further comprises a fixing member; the fixing member comprises a spring and a positioning pillar; one end of the spring is connected to an inner side surface of the front frame, and the other end of the spring is connected to the positioning pillar; in a spring force action of the spring, the positioning pillar extends from the inner side surface of the front frame for a predetermined distance and extends into the positioning hole of the side wall, so as to engage and connect with the back plate; and the front frame and the side wall of the back plate are fixed and connected, so as to fix and connect the front frame and the back plate.

2. The display device according to claim 1, wherein the fixing member further comprises a limiting part; the limiting part comprises a limiting ring and a connecting portion connected to the limiting ring; and the limiting part is fixed and connected to the front frame by the connecting portion; and
wherein the positioning pillar comprises a first base and a positioning rod, and the positioning rod passes through the limiting ring, so that the limiting ring limits the first base between the limiting part and the front frame.

3. The display device according to claim 2, wherein the display device further comprises a second base disposed between the spring and the inner side surface of the front frame, and the second base is fixed and connected on the front frame.

4. The display device according to claim 3, wherein the connecting portion of the limiting part is fixed and connected to the second base.

5. The display device according to claim 1, wherein the positioning hole has a first depth, and the first depth is less than the thickness of the side wall.

6. The display device according to claim 1, wherein the positioning hole has a first depth, and the first depth is equal to the thickness of the side wall.

7. The display device according to claim 3, wherein the second base is fixed and connected on the inner side surface of the front frame by sticking.

8. The display device according to claim 1, wherein the front frame is fixed and connected to the back frame by sticking or screw-connection.

9. A display device, comprising a front frame, a back plate and a back frame, wherein the back frame comprises a loading surface loading the back plate and a plurality of side edges disposed around the loading surface; and the side edges of the back frame is fixed and connected to the front frame;
wherein the back plate is disposed on the loading surface of the back frame, and the back plate comprises a back plate body and a plurality of side walls protruded on each of side edges of the back plate body; and
wherein the backlight module further comprises a fixing member, and the front frame and the side wall of the back plate are fixed and connected by the fixing member, so as to fix and connect the front frame and the back plate.

10. The display device according to claim 9, wherein the side wall of the back plate is formed with a positioning hole; the fixing member comprises a spring and a positioning pillar; and one end of the spring is connected to an inner side surface of the front frame, and the other end of the spring is connected to the positioning pillar; and
wherein in a spring force action of the spring, the positioning pillar extends from the inner side surface of the front frame for a predetermined distance, and extends into the positioning hole of the side wall, so as to engage and connect with the back plate.

11. The display device according to claim 10, wherein the fixing member further comprises a limiting part, and the limiting part comprises a limiting ring and a connecting portion connected to the limiting ring, and the limiting part is fixed and connected to the front frame by the connecting portion; and
wherein the positioning pillar comprises a first base and a positioning rod, and the positioning rod passes through the limiting ring, so that the limiting ring limits the first base between the limiting part and the front frame.

12. The display device according to claim 11, wherein the display device further comprises a second base disposed between the spring and the inner side surface of the front frame, and the second base is fixed and connected on the front frame.

13. The display device according to claim 12, wherein the connecting portion of the limiting part is fixed and connected to the second base.

14. The display device according to claim 10, wherein the positioning hole has a first depth, and the first depth is less than the thickness of the side wall.

15. The display device according to claim 10, wherein the positioning hole has a first depth, and the first depth is equal to the thickness of the side wall.

16. The display device according to claim 12, wherein the second base is fixed and connected on the inner side surface of the front frame by sticking.

17. The display device according to claim 9, wherein the side walls of the back plate and the back plate body are integrated into one body.

18. The display device according to claim 9, wherein the front frame is fixed and connected to the back frame by sticking or screw-connection.
